(19) United States
(12) Patent Application Publication
(10) Pub. No.: US 2026/0171138 A1
(43) Pub. Date: Jun. 18, 2026

(54) MEMORY DEVICE INCLUDING LEAKAGE CURRENT CONTROL CIRCUIT

(71) Applicant: SAMSUNG ELECTRONICS CO., LTD., Suwon-si (KR)

(72) Inventors: Min Sang PARK, Suwon-si (KR); Min-Soo JANG, Suwon-si (KR); Chang Sik YOO, Suwon-si (KR); Jeong Don IHM, Suwon-si (KR); Yun Sang CHO, Suwon-si (KR)

(73) Assignee: SAMSUNG ELECTRONICS CO., LTD., Suwon-si (KR)

(21) Appl. No.: 19/328,867

(22) Filed: Sep. 15, 2025

(30) Foreign Application Priority Data
Dec. 17, 2024 (KR) 10-2024-0188739

(51) Int. Cl. G11C 11/4074; G11C 29/50

(52) U.S. Cl. CPC G11C 11/4074; G11C 29/50004

(57) ABSTRACT

A memory device includes a memory cell array and a peripheral circuit region at least partially overlapping the memory cell array in a first direction. The peripheral circuit region includes a bias voltage generating circuit configured to generate a bias voltage and to provide the bias voltage to an individual circuit of the peripheral circuit region, and a leakage current control circuit configured to generate a bias voltage control signal and to control, using the bias voltage control signal, a magnitude of a leakage current generated in the peripheral circuit region by the bias voltage. The leakage current control circuit includes a test circuit configured to generate a test voltage based on the bias voltage, a reference circuit configured to generate a reference voltage based on a power voltage, and a differential amplifier configured to generate the bias voltage control signal by comparing the test voltage with the reference voltage.

### CROSS-REFERENCE TO RELATED APPLICATION

This application claims priority under 35 U.S.C. § 119 to Korean Patent Application No. 10-2024-0188739, filed on Dec. 17, 2024, in the Korean Intellectual Property Office, the disclosure of which is incorporated by reference herein in its entirety.

### BACKGROUND

### 1. Field

The present disclosure relates generally to a memory device, and more particularly, to a memory device including a leakage current control circuit.

### 2. Description of Related Art

Memory devices may be classified into volatile at least one of memory devices or non-volatile memory devices depending on whether stored data is lost when power supply to the memory device is interrupted.

A volatile memory device may refer to a memory cell array that may include a plurality of memory blocks, and each memory cell may include a transistor and a capacitor. A leakage current may occur in the transistor due to causes such as, but not limited to, degradation of the memory device. Accordingly, power consumption of the memory device may increase and/or reliability of the memory device may be reduced.

Thus, there exists a need for further improvements in memory device technology, as the need for improving power consumption and/or reliability of memory devices may be constrained by an inability to optimize the amount of leakage current in the memory devices. Improvements are presented herein. These improvements may also be applicable to other semiconductor technologies.

### SUMMARY

One or more example embodiments of the present disclosure provide a memory device with improved reliability, when compared to related memory devices.

Further, one or more example embodiments of the present disclosure provide a memory device including a leakage current control circuit capable of optimizing an amount of leakage current in the memory device.

The present disclosure is not limited to the embodiments mentioned above and additional embodiments of the present disclosure, which may not be mentioned herein, may be clearly by those skilled in the art from the following description of the present disclosure.

According to an aspect of the present disclosure, a memory device includes a memory cell array including a plurality of memory transistors and a memory capacitor, and a peripheral circuit region at least partially overlapping the memory cell array in a first direction. The peripheral circuit region includes a bias voltage generating circuit configured to generate a bias voltage and to provide the bias voltage to an individual circuit of the peripheral circuit region, and a leakage current control circuit configured to generate a bias voltage control signal and to control, using the bias voltage control signal, a magnitude of a leakage current generated in the peripheral circuit region by the bias voltage. The leakage current control circuit includes a test circuit configured to generate a test voltage based on the bias voltage, a reference circuit configured to generate a reference voltage based on a power voltage, and a differential amplifier configured to generate the bias voltage control signal by comparing the test voltage with the reference voltage. The test circuit includes a first transistor having a first threshold voltage and a second transistor having a second threshold voltage different from the first threshold voltage. The reference circuit includes a third transistor having the first threshold voltage and a fourth transistor having the second threshold voltage.

According to an aspect of the present disclosure, a memory device includes a memory cell array including a plurality of memory transistors and a memory capacitor, and a peripheral circuit region at least partially overlapping the memory cell array in a first direction. The peripheral circuit region includes a bias voltage generating circuit configured to generate a bias voltage and to provide the bias voltage to an individual circuit of the peripheral circuit region, and a leakage current control circuit configured to generate a bias voltage control signal and to control, using the bias voltage control signal, a magnitude of a leakage current generated in the peripheral circuit region by the bias voltage. The leakage current control circuit includes a test circuit configured to generate a test voltage based on the bias voltage, and a reference circuit configured to generate a reference voltage based on a power voltage. The leakage current control circuit is further configured to generate the bias voltage control signal that controls the bias voltage generating circuit to generate the bias voltage such that a magnitude of the test voltage is equal to a magnitude of the reference voltage.

According to an aspect of the present disclosure, a memory device includes a memory cell array including a plurality of memory transistors and a memory capacitor, and a peripheral circuit region at least partially overlapping the memory cell array in a first direction. The peripheral circuit region includes a bias voltage generating circuit configured to generate a bias voltage and to provide the bias voltage to an individual circuit of the peripheral circuit region, and a leakage current control circuit configured to generate a bias voltage control signal and to control, using the bias voltage control signal, a magnitude of a leakage current generated in the peripheral circuit region by the bias voltage. The leakage current control circuit includes a test circuit configured to generate a test voltage based on the bias voltage, a reference circuit configured to generate a reference voltage based on a power voltage, and a differential amplifier configured to generate the bias voltage control signal based on the test voltage and the reference voltage. The test circuit includes a first transistor having a first threshold voltage and a second transistor having a second threshold voltage. The reference circuit includes a third transistor having the first threshold voltage and a fourth transistor having the second threshold voltage. The test circuit is further configured to generate the test voltage based on a first resistor and a test leakage current generated in the first transistor and the second transistor based on a first bias voltage being applied to a first body of the first transistor and a second body of the second transistor. The reference circuit is further configured to generate the reference voltage based on a second resistor and a reference leakage current generated in the third transistor and the fourth transistor based on the power voltage being applied to a third body of the third transistor and a fourth body of the fourth transistor. The differential amplifier is further configured to generate the bias voltage control signal based on the test voltage being different to the reference voltage. The bias voltage generating circuit is further configured to generate a second bias voltage based on the bias voltage control signal. The test circuit is further configured to generate a second test voltage based on the first resistor and a corrected test leakage current generated in the first transistor and the second transistor based on the second bias voltage being applied to the first body of the first transistor and the second body of the second transistor. A magnitude of the second test voltage is equal to a magnitude of the reference voltage.

Additional aspects may be set forth in part in the description which follows and, in part, may be apparent from the description, and/or may be learned by practice of the presented embodiments.

### BRIEF DESCRIPTION OF THE DRAWINGS

The above and other aspects, features, and advantages of certain embodiments of the present disclosure may be more apparent from the following description taken in conjunction with the accompanying drawings, in which:

FIG. 1 is a block diagram illustrating a memory system, according to some embodiments of the present disclosure;

FIG. 2 is a block diagram illustrating a memory chip of FIG. 1, according to some embodiments of the present disclosure;

FIG. 3 is a block diagram illustrating a partial configuration of the memory chip of FIG. 1, according to some embodiments of the present disclosure;

FIG. 4 is a diagram illustrating a bank array included in the memory chip of FIG. 3, according to some embodiments of the present disclosure;

FIG. 5 is a block diagram illustrating a leakage current control circuit, according to some embodiments of the present disclosure;

FIG. 6 is a circuit diagram illustrating a leakage current control circuit, according to some embodiments of the present disclosure;

FIGS. 7 and 8 are circuit diagrams illustrating an operation of the leakage current control circuit of FIG. 6, according to some embodiments of the present disclosure;

FIG. 9 is a circuit diagram illustrating a leakage current control circuit, according to some embodiments of the present disclosure;

FIG. 10 is a block diagram illustrating a leakage current control circuit, according to some embodiments of the present disclosure; and

FIG. 11 is a schematic block diagram illustrating an electronic device including a memory device, according to some embodiments of the present disclosure.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, or the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, or the like may be used to distinguish components from each other and do not limit the present disclosure. For example, the terms “first”, “second”, “third”, or the like may not necessarily involve an order or a numerical meaning of any form.

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

The embodiments herein may be described and illustrated in terms of blocks, as shown in the drawings, which carry out a described function or functions. These blocks, which may be referred to herein as units or modules or the like, or by names such as device, logic, circuit, controller, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, or the like.

In the present disclosure, the articles “a” and “an” are intended to include one or more items, and may be used interchangeably with “one or more.” Where only one item is intended, the term “one” or similar language is used. For example, the term “a processor” may refer to either a single processor or multiple processors. When a processor is described as carrying out an operation and the processor is referred to perform an additional operation, the multiple operations may be executed by either a single processor or any one or a combination of multiple processors.

Hereinafter, various embodiments of the present disclosure are described with reference to the accompanying drawings.

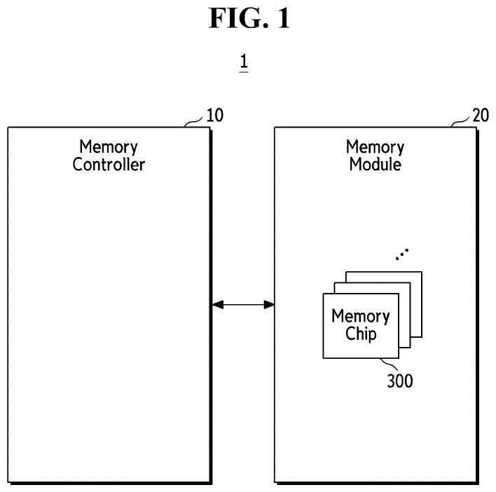

FIG. 1 is a block diagram illustrating a memory system, according to some embodiments of the present disclosure.

Referring to FIG. 1, a memory system 1 may include a memory controller 10 and a memory module 20. Each of the memory controller 10 and the memory module 20 may include an interface for mutual communication. The interfaces may be connected to each other through a control bus for transmitting a command CMD, an address ADDR, a clock signal CLK, or the like, and/or a data bus for transmitting data. The command CMD may be regarded as including the address ADDR.

The memory controller 10 may generate a command CMD for controlling the memory module 20, and data DATA may be written in and/or may be read from the memory module 20 under the control of the memory controller 10.

The memory module 20 may include a plurality of memory chips 300. Each of the memory chips 300 may be implemented in an independent chip form and packaged in a substrate of the memory module 20. The memory module 20 may transmit data read from a memory cell, state information of a memory device, or the like to the memory controller 10 through the data bus.

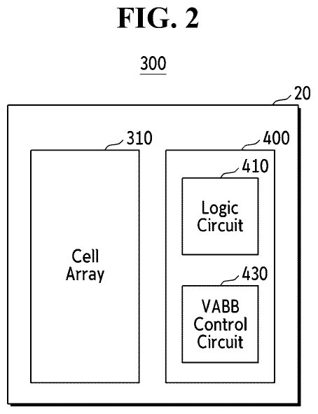

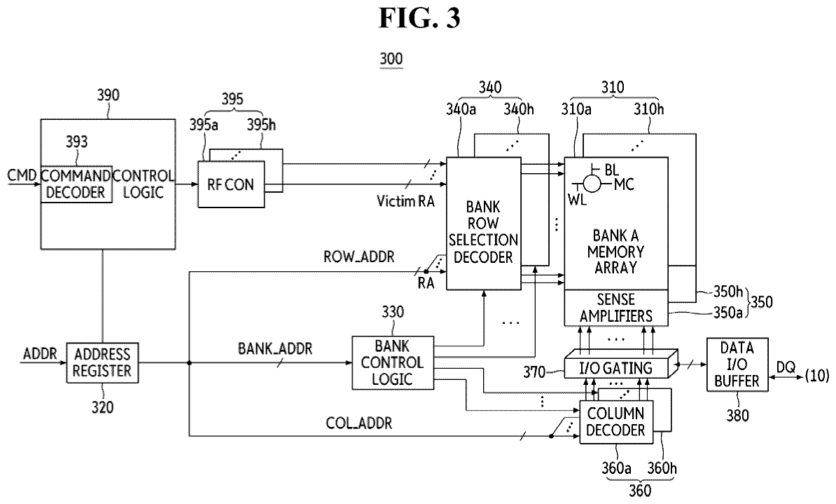

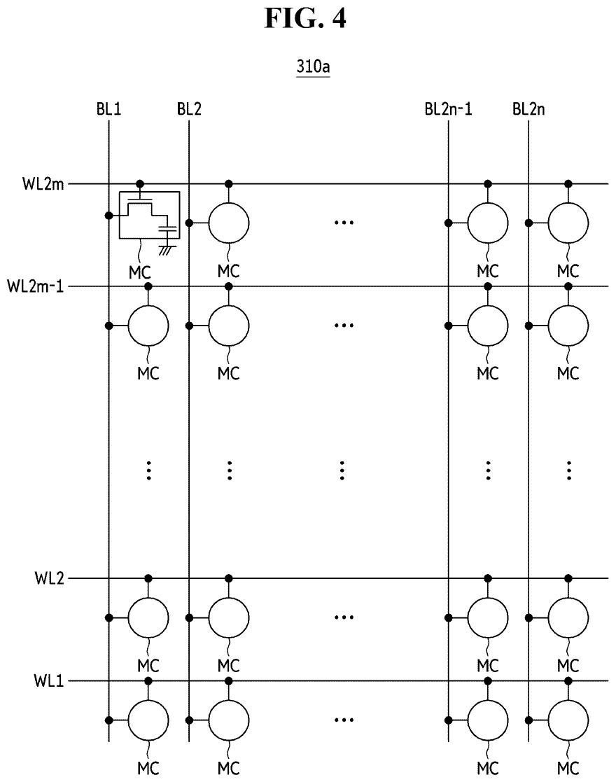

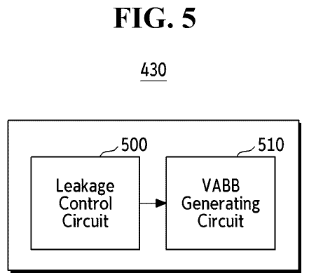

FIG. 2 is a block diagram illustrating a memory chip of FIG. 1, according to some embodiments of the present disclosure. FIG. 3 is a block diagram illustrating a partial configuration of the memory chip of FIG. 1, according to some embodiments of the present disclosure. FIG. 4 is a diagram illustrating a bank array included in the memory chip of FIG. 3, according to some embodiments of the present disclosure. FIG. 5 is a block diagram illustrating a leakage current control circuit, according to some embodiments of the present disclosure.

Referring to FIGS. 2 to 5, the memory chip 300 may include a memory cell array 310 and a peripheral circuit region 400.

The memory cell array 310 may include a plurality of bank arrays (e.g., a first bank array 310a to an h-th bank array 310h, where h is a positive integer greater than zero (0)). Each bank array of the plurality of bank arrays 310a to 310h may include a plurality of memory cells MC. For example, the memory cell MC may be and/or may include a dynamic random access memory (DRAM) cell. As another example, the memory interface may perform communication based on one or more memory interface standards such as, but not limited to, double data rate (DDR), low power double data rate (LPDDR), graphics double data rate (GDDR), wide input/output (I/O), high bandwidth memory (HBM), hybrid memory cube (HMC), or the like.

The memory cell MC may be arranged at a point where a plurality of word lines WL (e.g., a first word line WL1, a second word line WL2, to an (2m-1)-th word line WL2m-1, and an (2m)-th word line BL2m, where m is a positive integer greater than zero (0)) may intersect a plurality of bit lines BL (e.g., a first bit line BL1, a second bit line BL2, to an (2n-1)-th bit line BL2n-1, and an (2n)-th bit line BL2n, where n is a positive integer greater than zero (0)). That is, each of the memory cells MC may be connected to a single word line WL and a single bit line BL.

Each memory cell MC may include a switch element and an information storage capacitor. In an embodiment, the switch element may include a transistor, a gate terminal of the transistor may be connected to the word line WL, and drain/source terminals of the transistor may be connected to the bit line BL and the information storage capacitor, respectively.

The peripheral circuit region 400 may include a logic circuit 410 and a bias voltage (VABB) control circuit 430.

In some embodiments, the logic circuit 410 may include a memory control logic 390, an address register 320, a bank control logic 330, a row selecting circuit 340, a column decoder 360, a sense amplifier unit 350, an I/O gating circuit 370, a data I/O buffer 380, and a refresh controller 395.

The row selecting circuit 340 may include a plurality of bank row selecting circuits (e.g., a first bank row selecting circuit 340a to an h-th bank row selecting circuit 340h) connected to the plurality of bank arrays 310a to 310h. The column decoder 360 may include a plurality of column decoders (e.g., a first column decoder 360a to an h-th column decoder 360h) connected to the plurality of bank arrays 310a to 310h. The sense amplifier unit 350 may include a plurality of sense amplifiers (e.g., a first sense amplifier 350a to an h-th sense amplifier 350h) that may be connected to the plurality of bank arrays 310a to 310h, respectively.

The address register 320 may receive address information from the memory controller 10. The address information ADD may include a bank address BANK_ADDR, a row address ROW_ADDR, and/or a column address COL_ADDR. The address register 320 may convert address information into an internal address of the memory module 20. For example, the address register 320 may provide the bank address BANK_ADDR to the bank control logic 330, the row address ROW_ADDR to the row selecting circuit 340, and the column address COL_ADDR to the column decoder 360.

The bank control logic 330 may generate bank control signals in response to the bank address BANK_ADDR. In response to the bank control signals, a bank row selecting circuit, which may correspond to the bank address BANK_ADDR, from among the plurality of bank row selecting circuits 340a to 340h may be activated, and a bank column decoder, which may correspond to the bank address BANK_ADDR, from among the plurality of bank column decoders 360a to 360h may be activated.

The row address ROW_ADDR output from the address register 320 may be applied to each of the plurality of bank row selecting circuits 340a to 340h. Among the bank row selecting circuits 340a to 340h, a bank row selecting circuit activated by the bank control logic 330 may decode the row address ROW_ADDR to activate a word line corresponding to the row address and apply an operating voltage. For example, the activated bank row selecting circuit may apply a word line driving voltage to each row corresponding to the row address. In this case, an active command may be and/or may include a command for a data read operation, a write operation, and/or an erase operation with respect to the memory cell. A refresh command may be a command for performing a refresh operation for at least one of a row hammer row or a sacrificial row.

The column decoder 360 may include a column address latch. The column address latch may receive the column address COL_ADDR from the address register 320 and may temporarily store the received column address COL_ADDR. In addition, the column address latch may gradually increase the received column address COL_ADDR in a burst mode. The column address latch may apply the temporarily stored and/or gradually increased column address COL_ADDR to each of the plurality of bank column decoders 360a to 360h.

The bank column decoder activated by the bank control logic 330 from among the plurality of bank column decoders 360a to 360h may activate a sense amplifier corresponding to the bank address BANK_ADDR and the column address COL_ADDR through the I/O gating circuit 370.

The I/O gating circuit 370 may include an input data mask logic, read data latches for storing data output from the plurality of bank arrays 310a to 310h, and write drivers for writing data in the plurality of bank arrays 310a to 310h, along with circuits for gating I/O data.

The data DQ to be read from one of the plurality of bank arrays 310a to 310h may be sensed by one of the plurality of sense amplifiers 350a to 350h, which may correspond to one of the plurality of bank arrays 310a to 310h, and may be stored in the read data latches. The data DQ stored in the read data latches may be provided to the memory controller through the data I/O buffer 380. The data DQ to be written in one of the plurality of bank arrays 310a to 310h may be provided from the memory controller to the data I/O buffer 380. The data DQ provided to the data I/O buffer 380 may be written in one of the plurality of bank arrays 310a to 310h through the write drivers.

The refresh controller 395 may control the bank row selecting circuit 340 of the memory module 20 to perform a refresh operation. According to some embodiments, the refresh controller 395 may include a plurality of refresh controllers (e.g., a first refresh controller 395a to an h-th refresh controller 395h) respectively corresponding to the plurality of bank row selecting circuits 340a to 340h.

The memory control logic 390 may control the overall operation of the memory chip 300. According to some embodiments, the memory control logic 390 may generate first control signals to perform an activation operation (e.g., a write operation or a read operation) for the memory chip 300. According to some embodiments, the memory control logic 390 may control the refresh controller 395 by a refresh controller control signal to perform a refresh operation for the memory chip 300.

The VABB control circuit 430 may control a threshold voltage of a metal oxide semiconductor (MOS) transistor by generating a bias voltage and applying the bias voltage to a body of the MOS transistor included in the peripheral circuit in the memory chip 300.

In some embodiments, the VABB control circuit 430 may include a leakage current control circuit 500 and a bias voltage (VABB) generating circuit 510. The leakage current control circuit 500 may periodically (and/or aperiodically) measure a leakage current according to the bias voltage provided to the memory chip 300, and may determine an optimal bias voltage. The VABB generating circuit 510 may receive a bias voltage control signal from the leakage current control circuit 500 and may generate the optimal bias voltage. The generated bias voltage may be applied to the body of the transistor included in the peripheral circuit in the memory chip 300 again. Accordingly, a memory device that maintains an optimal operation state regardless of a temperature or a process step may be provided. Configurations and operations of the leakage current control circuit 500 and the VABB generating circuit 510 are described below.

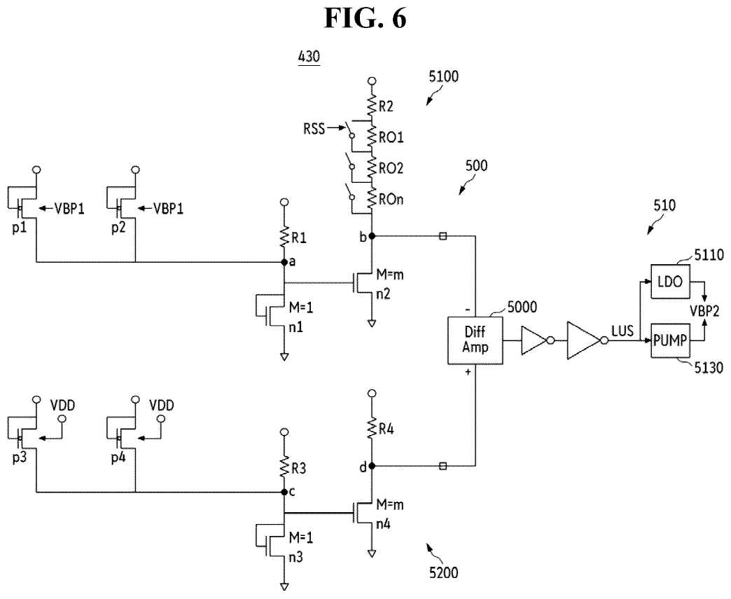

FIG. 6 is a circuit diagram illustrating a leakage current control circuit, according to some embodiments of the present disclosure.

Referring to FIG. 6, the VABB control circuit 430 may include a leakage current control circuit 500 and a VABB generating circuit 510. The leakage current control circuit 500 may provide a bias voltage control signal LUS to the VABB generating circuit 510.

In some embodiments, the leakage current control circuit 500 may control the VABB generating circuit 510 to generate an optimal bias voltage by performing a test in which the bias voltage is applied to the body of the transistor in the memory chip 300 and generating the bias voltage control signal LUS.

The leakage current control circuit 500 may include a test circuit 5100, a reference circuit 5200, and a differential amplifier 5000. One end of the test circuit 5100 and one end of the reference circuit 5200 may be electrically connected to an inverting terminal and a non-inverting terminal of the differential amplifier 5000, respectively.

In some embodiments, the test circuit 5100 may include first test transistor p1 and second transistor p2 that may be connected to a first node ‘a’ in parallel. The first transistor p1 and the second transistor p2 may be transistors having characteristics similar to those of the transistor included in the peripheral circuit of the memory chip 300. For example, the transistor included in the memory chip 300 may include a transistor having a first threshold voltage and a transistor having a second threshold voltage with a magnitude different from a magnitude of the first threshold voltage. For example, when the transistor with a first threshold voltage and the transistor with a second threshold voltage, included in the peripheral circuit 400 of a memory chip 300, have sizes of 10 micrometer (μm) and 80 μm respectively, the first transistor p1 and the second transistor p2 included in the test circuit 5100 may have sizes of 1 μm and 8 μm, respectively. However, embodiments of the present disclosure are not limited thereto. That is, the test circuit 5100 may include multiple transistors with the same size ratio as the transistors included in the memory chip 300. The first transistor p1 included in the test circuit 5100 may be a transistor having a first threshold voltage, and the second transistor p2 may be a transistor having a second threshold voltage.

In some embodiments, a magnitude ratio of the transistor having a first threshold voltage and the transistor having a second threshold voltage, which are included in the memory chip 300, may be n:m (where n and m are positive integers greater than zero (0)). For example, a magnitude ratio of the first transistor p1 and the second transistor p2 may be represented as n:m. Although the drawings illustrate a case where there are two (2) transistors with different threshold voltages in the memory chip 300, embodiments of the present disclosure are not limited thereto. For example, a transistor having a third threshold voltage may be included in the memory chip 300. That is, there may be three (3) transistors with different threshold voltages in the memory chip 300. The transistor with the first threshold voltage, the transistor with the second threshold voltage, and the transistor with the third threshold voltage may have a size ratio of n:m:l. In such a case, the test circuit 5100 may include multiple transistors with the same size ratio (e.g., n:m:l) as the transistors included in the memory chip 300.

In some embodiments, a first bias voltage VBP1 may be applied to the bodies of the first transistor p1 and the second transistor p2.

The test circuit 5100 may include a first resistor R1 and test current mirrors (e.g., a first test current mirror n1 and a second test current mirror n2), which may be connected to the first node ‘a’. The first and second test current mirrors n1 and n2 may respectively include a third transistor n1 and a fourth transistor n2. Gate and drain terminals of the third transistor n1 and a gate terminal of the fourth transistor n2 may be electrically connected to the first node ‘a’. A drain terminal of the fourth transistor n2 may be electrically connected to second resistors R2, RO1, RO2, and ROn at a second node ‘b’. The second resistors R2, RO1, RO2, and ROn may include a first sub-resistor R2 and second sub-resistors RO1, RO2, and ROn.

In some embodiments, magnitudes of the second sub-resistors RO1, RO2, and ROn may vary depending on a resistance selection signal RSS. The resistance selection signal RSS is described below.

In some embodiments, the reference circuit 5200 may include reference transistors p3 and p4 that may be connected to a third node ‘c’ in parallel. The reference transistors p3 and p4 may include a fifth transistor p3 and a sixth transistor p4. The fifth transistor p3 and the sixth transistor p4 may be transistors having characteristics similar to those of the transistor included in the peripheral circuit of the memory chip 300. For example, the transistor included in the memory chip 300 may include a transistor having a first threshold voltage and a transistor having a second threshold voltage with a magnitude different from a magnitude of the first threshold voltage. For example, when the transistor with a first threshold voltage and the transistor with a second threshold voltage, included in the peripheral circuit 400 of a memory chip 300, have sizes of 10 μm and 80 μm respectively, the fifth transistor p3 and the sixth transistor p4 included in the reference circuit 5200 may have sizes of 1 μm and 8 μm, respectively. However, embodiments of the presented disclosure may not be limited thereto. That is, the reference circuit 5200 may include multiple transistors with the same size ratio as the transistors included in the memory chip 300. The fifth transistor p3 included in the reference circuit 5200 may be a transistor having a first threshold voltage, and the sixth transistor p4 may be a transistor having a second threshold voltage.

In some embodiments, a magnitude ratio of the transistor having a first threshold voltage and the transistor having a second threshold voltage, which are included in the memory chip 300, may be n:m. That is, a magnitude ratio of the fifth transistor p3 and the sixth transistor p4 may be represented as n:m. Although the drawings illustrate a case with two (2) transistors with different threshold voltages in the memory chip 300, embodiments of the present disclosure are not limited thereto. For example, a transistor having a third threshold voltage may be included in the memory chip 300. That is, there may be three (3) transistors with different threshold voltages in the memory chip 300. The transistor with the first threshold voltage, the transistor with the second threshold voltage, and the transistor with the third threshold voltage may have a size ratio of n:m:l. In such a case, the test circuit 5100 may include multiple transistors with the same size ratio (e.g., n:m:l) as the transistors included in the memory chip 300.

In some embodiments, a power voltage VDD may be applied to the bodies of the fifth transistor p3 and the sixth transistor p4.

The reference circuit 5200 may include a third resistor R3 and reference current mirrors n3 and n4, which may be connected to the third node ‘c’. The reference current mirrors n3 and n4 may include a seventh transistor n3 and an eighth transistor n4. Gate and drain terminals of the seventh transistor n3 and a gate terminal of the eighth transistor n4 may be electrically connected to the third node ‘c’. A drain terminal of the eighth transistor n4 may be electrically connected to a fourth resistor R4 at a fourth node ‘d’. Magnitudes of the first resistor R1 and the third resistor R3 may be substantially similar to and/or the same as each other. Magnitudes of the first sub-resistor R2 and the fourth resistor R4 may be substantially similar to and/or the same as each other. That is, the test circuit 5100 and the reference circuit 5200 may correspond to circuits different from each other in a bias voltage applied to the body of the transistor and magnitudes of resistors connected to the second node ‘b’ and the fourth node ‘d’.

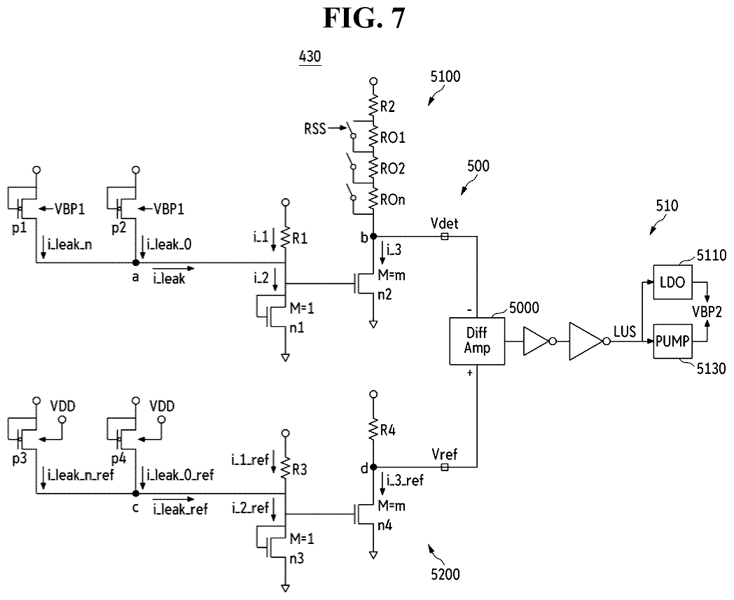

In some embodiments, the differential amplifier 5000 may receive a test voltage (e.g., Vdet of FIG. 7) and a reference voltage (e.g., Vref of FIG. 7) from the test circuit 5100 and the reference circuit 5200. The test voltage Vdet may correspond to a voltage measured at the second node ‘b’, and the reference voltage Vref may correspond to a voltage measured at the fourth node ‘d’.

The differential amplifier 5000 may compare the test voltage Vdet with the reference voltage Vref and generate a bias voltage control signal LUS for adjusting the magnitude of the bias voltage. The VABB generating circuit 510 may receive the bias voltage control signal LUS from the leakage current control circuit 500 and generate a corrected bias voltage by using the regulator 5110 and the charge pump 5130.

The regulator 5110 and the charge pump 5130 may convert an input voltage to output an output voltage. In some embodiments, the regulator 5110 may be a low dropout voltage regulator.

The corrected bias voltage may be provided to the transistor in the memory chip 300, and after a predetermined time elapses, the VABB control circuit 430 may perform a test for the corrected bias voltage. As a result, a memory device that maintains an optimal operation state regardless of a temperature or a process step may be provided.

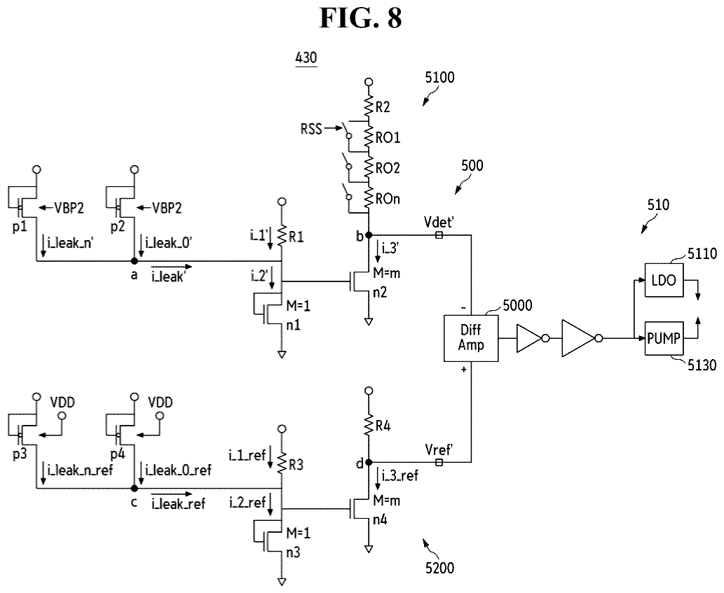

FIGS. 7 and 8 are circuit diagrams illustrating an operation of the leakage current control circuit of FIG. 6, according to some embodiments of the present disclosure.

Referring to FIGS. 6 and 7, in the test circuit 5100, the first bias voltage VBP1 may be applied to the bodies of the first transistor p1 and the second transistor p2. A first test leakage current i_leak_n may occur from the first transistor p1, and a second test leakage current i_leak_0 may occur from the second transistor p2. The first test leakage current i_leak_n and the second test leakage current i_leak_0 may be combined at the first node ‘a’ to become a test leakage current i_leak, and the test leakage current i_leak may be combined with a first current i_1 flowing in the first resistor R1 between the power voltage VDD and the first node ‘a’ to become a second current i_2. A third current i_3 may be determined based on the second current i_2. For example, when the magnitudes of the third transistor n1 and the fourth transistor n2 are 1:m, a ratio of the second current i_2 to the third current i_3 may be 1:m. The test voltage Vdet may be a voltage drop caused by the second resistors R2, RO1, RO2 and ROn between the power voltage VDD and the second node ‘b’ and the third current i_3.

In the reference circuit, the power voltage VDD may be applied to the bodies of the fifth transistor p3 and the sixth transistor p4. A first reference leakage current i_leak_n_ref may occur from the fifth transistor p3, and a second reference leakage current i_leak_0_ref may occur from the sixth transistor p4. The first reference leakage current i_leak_n_ref and the second reference leakage current i_leak_0_ref may be combined at the third node ‘c’ to become a reference leakage current i_leak_ref, and the reference leakage current i_leak_ref may be combined with the first reference current i_1_ref flowing in the third resistor R3 between the power voltage VDD and the third node ‘c’ to become the second reference current i_2_ref. A third reference current i_3_ref may be determined based on the second reference current i_2_ref. For example, when magnitudes of the seventh transistor n3 and the eighth transistor n4 are 1:m, a ratio of the second reference current i_2_ref to the third reference current i_3_ref may be 1:m. The reference voltage Vref may be a voltage drop caused by the fourth resistor R4 between the power voltage VDD and the fourth node ‘d’ and the third reference current i_3_ref.

The differential amplifier 5000 may compare the test voltage Vdet with the reference voltage Vref and generate a bias voltage control signal LUS for adjusting the magnitude of the bias voltage.

For example, when the test voltage Vdet is greater than the reference voltage Vref, the bias voltage control signal LUS may be a signal for decreasing the magnitude of a leakage current generated in the test transistors p1 and p2. That is, the bias voltage control signal LUS may correspond to a signal for increasing the magnitude of the bias voltage.

As another example, when the test voltage Vdet is less than the reference voltage Vref, the bias voltage control signal LUS may be a signal for increasing the magnitude of the leakage current generated in the test transistors p1 and p2. That is, the bias voltage control signal LUS may correspond to a signal for decreasing the magnitude of the bias voltage.

The VABB generating circuit 510 may receive the bias voltage control signal LUS from the leakage current control circuit 500 and may generate a second bias voltage VBP2 by using a regulator 5110 and a charge pump 5130.

For example, when the test voltage Vdet is greater than the reference voltage Vref, the second bias voltage VBP2 may be greater than the first bias voltage VBP1.

As another example, when the test voltage Vdet is less than the reference voltage Vref, the second bias voltage VBP2 may be less than the first bias voltage VBP1.

Referring to FIGS. 6 and 8, the second bias voltage VBP2 may be provided to the transistor in the memory chip 300, and after a predetermined time elapses, the VABB control circuit 430 may perform a test for the second bias voltage VBP2.

In the test circuit 5100, the second bias voltage VBP2 may be applied to the bodies of the first transistor p1 and the second transistor p2. A third test leakage current i_leak_n′ may occur from the first transistor p1, and a fourth test leakage current i_leak_0′ may occur from the second transistor p2. The third test leakage current i_leak_n′ and the fourth test leakage current i_leak_0′ may be combined at the first node ‘a’ to become a corrected test leakage current i_leak′, and the corrected test leakage current i_leak′ may be combined with the first corrected current i_1′ flowing in the first resistor R1 between the power voltage VDD and the first node ‘a’ to become a second correction current i_2′. A third corrected current i_3′ may be determined based on the second corrected current i_2′. For example, when the magnitudes of the third transistor n1 and the fourth transistor n2 are 1:m, a ratio of the second corrected current i_2′ to the third corrected current i_3′ may be 1:m. A corrected test voltage Vdet′ may be a voltage drop caused by the second resistors R2, RO1, RO2, and ROn between the power voltage VDD and the second node ‘b’ and the third corrected current i_3′.

In the reference circuit, the power voltage VDD may be applied to the bodies of the fifth transistor p3 and the sixth transistor p4. The first reference leakage current i_leak_n_ref may occur from the fifth transistor p3, and the second reference leakage current i_leak_0_ref may occur from the sixth transistor p4. The first reference leakage current i_leak_n_ref and the second reference leakage current i_leak_0_ref may be combined at the third node ‘c’ to become a reference leakage current i_leak_ref, and the reference leakage current i_leak_ref may be combined with a first reference current i_1_ref flowing in the third resistor R3 between the power voltage VDD and the third node ‘c’ to become a second reference current i_2_ref. A third reference current i_3_ref may be determined based on the second reference current i_2_ref. For example, when the magnitudes of the seventh transistor n3 and the eighth transistor n4 are 1:m, a ratio of the second reference current i_2_ref to the third reference current i_3_ref may be 1:m. The reference voltage Vref may be a voltage drop caused by the fourth resistor R4 between the power voltage VDD and the fourth node ‘d’ and the third reference current i_3_ref.

The differential amplifier 5000 may compare the corrected test voltage Vdet′ with the reference voltage Vref and generate the bias voltage control signal LUS for adjusting the magnitude of the bias voltage.

For example, when the magnitude of the corrected test voltage Vdet′ is equal to the magnitude of the reference voltage Vref, the differential amplifier 5000 may not generate the bias voltage control signal LUS. That is, the second bias voltage VBP2 may correspond to an optimal bias voltage for operating the memory chip 300. As a result, a memory device that maintains an optimal operation state regardless of a temperature or a process step may be provided.

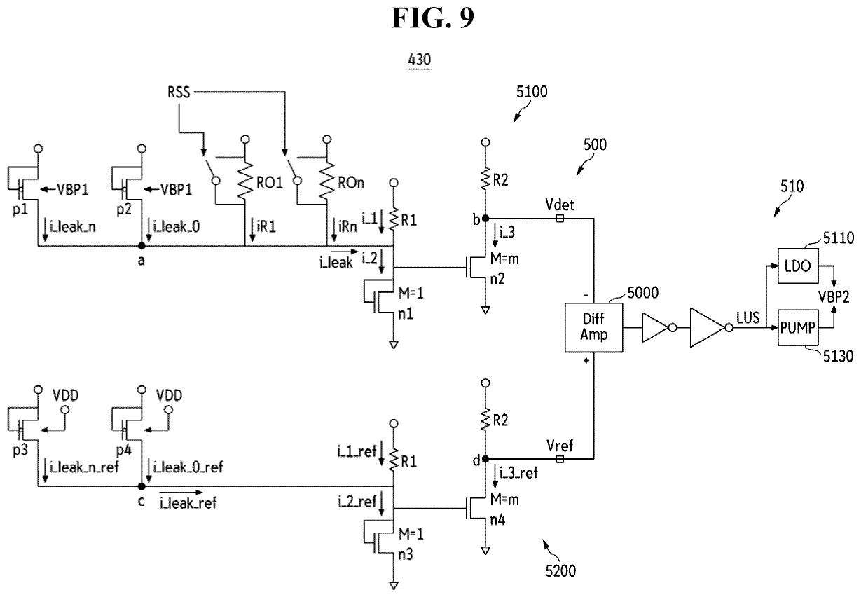

FIG. 9 is a circuit diagram illustrating a leakage current control circuit, according to some embodiments of the present disclosure. The leakage current control circuit of FIG. 9 may include and/or may be similar in many respects to the leakage current control circuit described above with reference to FIG. 6, and may include additional features not mentioned above. Consequently, repeated descriptions of the leakage current control circuit described above with reference to FIG. 6 may be omitted for the sake of brevity.

Referring to FIG. 9, the VABB control circuit 430 may include a leakage current control circuit 500 and a VABB generating circuit 510. The leakage current control circuit 500 may provide a bias voltage control signal LUS to the VABB generating circuit 510.

The leakage current control circuit 500 may perform a test by using the bias voltage applied to the body of a transistor in the memory chip 300, generate the bias voltage control signal LUS, and control the VABB generating circuit 510 to generate an optimal bias voltage. The leakage current control circuit 500 may include a test circuit 5100, a reference circuit 5200, and a differential amplifier 5000. One ends of the test circuit 5100 and the reference circuit 5200 may be electrically connected to an inverting terminal and a non-inverting terminal of the differential amplifier 5000, respectively.

The test circuit 5100 may include test transistors p1 and p2 and offset resistors RO1 and Ron, which may be connected to the first node ‘a’ in parallel. The test transistors p1 and p2 may include a first transistor p1 and a second transistor p2. In some embodiments, magnitudes of the offset resistors RO1 and ROn may vary depending on a resistor selection signal RSS. The resistor selection signal RSS is described below.

In the test circuit 5100, a first bias voltage VBP1 may be applied to the bodies of the first transistor p1 and the second transistor p2. A first test leakage current i_leak_n may occur from the first transistor p1, and a second test leakage current i_leak_0 may occur from the second transistor p2. Based on the resistance selection signal RSS, a first offset current iR1 may occur in the first offset resistor RO1 between the power voltage VDD and the first node ‘a’, and a second offset current iRn may occur in the second offset resistor RON between the power voltage VDD and the second node ‘b’. The first test leakage current i_leak_n, the second test leakage current i_leak_0, the first offset current iR1, and the second offset current iRn may be combined at the first node ‘a’ to become a test leakage current i_leak, and the test leakage current i_leak may be combined with the first current i_1 flowing in the first resistor R1 between the power voltage VDD and the first node ‘a’ to become the second current i_2.

The test circuit 5100 may include a first resistor R1 and test current mirrors n1 and n2, which may be connected to the first node ‘a’. The test current mirrors n1 and n2 may include a third transistor n1 and a fourth transistor n2. Gate and drain terminals of the third transistor n1 and a gate terminal of the fourth transistor n2 may be electrically connected to the first node ‘a’. A drain terminal of the fourth transistor n2 may be electrically connected to the second resistor R2 at the second node ‘b’.

The third current i_3 may be determined based on the second current i_2. For example, when the magnitudes of the third transistor n1 and the fourth transistor n2 are 1:m, a ratio of the second current i_2 to the third current i_3 may be 1:m. The test voltage Vdet may be a voltage drop due to the second resistor R2 between the power voltage VDD and the second node ‘b’ and the third current i_3.

In some embodiments, the reference circuit 5200 may include reference transistors p3 and p4 connected to the third node ‘c’ in parallel. The reference transistors p3 and p4 may include a fifth transistor p3 and a sixth transistor p4.

In the reference circuit, the power voltage VDD may be applied to the bodies of the fifth transistor p3 and the sixth transistor p4. A first reference leakage current i_leak_n_ref may occur from the fifth transistor p3, and a second reference leakage current i_leak_0_ref may occur from the sixth transistor p4. The first reference leakage current i_leak_n_ref and the second reference leakage current i_leak_0_ref may be combined at the third node ‘c’ to become the reference leakage current i_leak_ref, and the reference leakage current i_leak_ref may be combined with the first reference current i_1_ref flowing in the third resistor R3 between the power voltage VDD and the third node ‘c’ to become the second reference current i_2_ref.

The reference circuit 5200 may include a third resistor R3 and reference current mirrors n3 and n4, which are connected to the third node ‘c’. The reference current mirrors n3 and n4 may include a seventh transistor n3 and an eighth transistor n4. Gate and drain terminals of the seventh transistor n3 and the gate terminal of the eighth transistor n4 may be electrically connected to the third node ‘c’. A drain terminal of the eighth transistor n4 may be electrically connected to the fourth resistor R4 at the fourth node ‘d’. The magnitudes of the first resistor R1 and the third resistor R3 may be substantially similar and/or the same as each other. The magnitudes of the second resistor R2 and the fourth resistor R4 may be substantially similar and/or the same as each other. That is, the test circuit 5100 and the reference circuit 5200 may correspond to circuits different from each other in a bias voltage applied to the body of the transistor and magnitudes of resistors connected to the first node ‘a’ and the third node ‘c’.

The third reference current i_3_ref may be determined based on the second reference current i_2_ref. For example, when the magnitudes of the seventh and eighth transistors n3 and n4 are 1:m, the ratio of the second reference current i_2_ref to the third reference current i_3_ref may be 1:m. The reference voltage Vref may be a voltage drop caused by the fourth resistor R4 between the power voltage VDD and the fourth node ‘d’ and the third reference current i_3_ref.

In some embodiments, the differential amplifier 5000 may receive the test voltage Vdet and the reference voltage Vref from the test circuit 5100 and the reference circuit 5200. The test voltage Vdet may correspond to the voltage measured at the second node ‘b’, and the reference voltage Vref may correspond to the voltage measured at the fourth node ‘d’.

The differential amplifier 5000 may compare the test voltage Vdet with the reference voltage Vref and generate the bias voltage control signal LUS for adjusting the magnitude of the bias voltage.

For example, when the test voltage Vdet is greater than the reference voltage Vref, the bias voltage control signal LUS may be a signal for decreasing the magnitude of the leakage current generated in the test transistors p1 and p2. That is, the bias voltage control signal LUS may correspond to a signal for increasing the magnitude of the bias voltage.

As another example, when the test voltage Vdet is less than the reference voltage Vref, the bias voltage control signal LUS may be a signal for increasing the magnitude of the leakage current generated in the test transistors p1 and p2. That is, the bias voltage control signal LUS may correspond to a signal for decreasing the magnitude of the bias voltage.

The VABB generating circuit 510 may receive the bias voltage control signal LUS from the leakage current control circuit 500 and may generate the corrected second bias voltage VBP2 by using the regulator 5110 and/or the charge pump 5130.

The regulator 5110 and the charge pump 5130 may convert an input voltage to output an output voltage. In some embodiments, the regulator 5110 may be a low dropout voltage regulator.

For example, when the test voltage Vdet is greater than the reference voltage Vref, the second bias voltage VBP2 may be greater than the first bias voltage VBP1.

As another example, when the test voltage Vdet is less than the reference voltage Vref, the second bias voltage VBP2 may be less than the first bias voltage VBP1.

In an embodiment, the second bias voltage VBP2 may be provided to the transistor in the memory chip 300, and after a predetermined time elapses, the VABB control circuit 430 may perform a test for the second bias voltage VBP2. As a result, a memory device that maintains an optimal operation state regardless of a temperature or a process step may be provided.

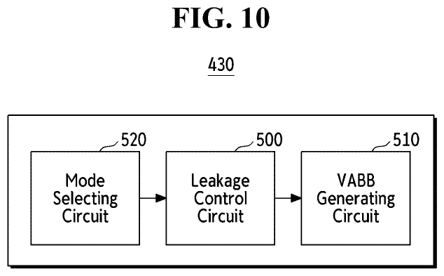

FIG. 10 is a block diagram illustrating a leakage current control circuit, according to some embodiments of the present disclosure.

Referring to FIG. 10, in some embodiments, the VABB control circuit 430 may include a leakage current control circuit 500, a VABB generating circuit 510, and a mode selecting circuit 520.

The mode selecting circuit 520 may generate a resistance selection signal RSS provided to the leakage current control circuit 500.

Referring to FIG. 6, the second sub-resistors RO1, RO2 and ROn may include a first offset resistor RO1, a second offset resistor RO2, and a third offset resistor ROn. Each of the first to third offset resistors RO1 to ROn may be connected to a switch.

In some embodiments, the second sub-resistors RO1, RO2 and ROn may vary depending on the resistance selection signal RSS. For example, when the memory chip 300 operates in a first mode (e.g., a self-refresh mode), the switch connected to the first offset resistor RO1 may be short-circuited by the resistance selection signal RSS. Alternatively, when the memory chip 300 operates in a second mode (e.g., a 2-Pin mode), the switch connected to the second offset resistor RO2 may be short-circuited by the resistance selection signal RSS. Accordingly, a bias voltage optimized for each mode may be searched and generated. Although three (3) offset resistors are shown in the drawing, this is exemplary, and the embodiments of the present disclosure are not limited thereto.

Referring to FIG. 9, the offset resistors RO1 and ROn may include a first offset resistor RO1 and a second offset resistor ROn. Each of the first offset resistor RO1 and the second offset resistor ROn may be connected to a switch.

In some embodiments, the offset resistors RO1 and ROn may vary depending on the resistance selection signal RSS. For example, when the memory chip 300 operates in a first mode (e.g., a self-refresh mode), the switch connected to the first offset resistor RO1 may be short-circuited by the resistance selection signal RSS. Alternatively, when the memory chip 300 operates in a second mode (e.g., a 2-Pin mode), the switch connected to the second offset resistor ROn may be short-circuited by the resistance selection signal RSS. Accordingly, the bias voltage optimized for each mode may be searched and generated. Although two (2) offset resistors are shown in the drawing, this is exemplary, and the embodiments of the present disclosure are not limited thereto.

Referring back to FIG. 10, the leakage current control circuit 500 may periodically measure the leakage current according to the bias voltage provided to the memory chip 300, and may determine an optimal bias voltage. The VABB generating circuit 510 may receive a bias voltage control signal from the leakage current control circuit 500, and may generate the optimal bias voltage. The generated bias voltage may be applied to the body of the transistor included in the peripheral circuit in the memory chip 300. As a result, the memory device that maintains an optimal operation state regardless of a temperature or a process step may be provided. Configurations and operations of the leakage current control circuit 500 and the VABB generating circuit 510 have been described above and may be omitted for the sake of brevity.

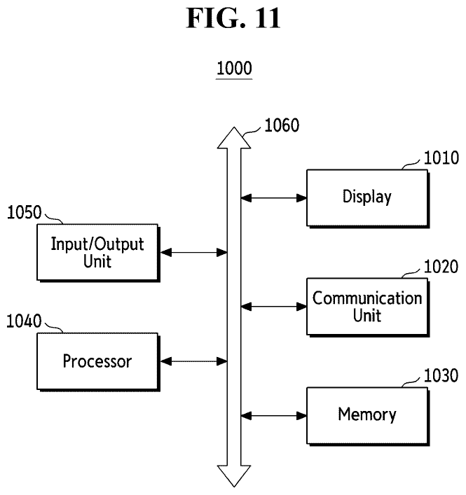

FIG. 11 is a schematic block diagram illustrating an electronic device including a memory device, according to some embodiments of the present disclosure.

Referring to FIG. 11, an electronic device 1000, according to some embodiments, may include a display 1010, a communication unit 1020, a memory 1030, a processor 1040, and an I/O unit 1050. Components such as, but not limited to, the display 1010, the communication unit 1020, the memory 1030, the processor 1040, and the I/O unit 1050 may perform communication with one another through a bus 1060. In addition to the above-described components, the electronic device 1000 may further include a power device, a port, or the like.

The processor 1040 may perform a specific computation, command, and task. The processor 1040 may be and/or may include a central processing unit (CPU), a microprocessor unit (MCU), an application processor (AP), or the like, and may perform communication with other components such as, but not limited to, the display 1010, the communication unit 1020, the memory 1030, and the I/O unit 1050 through the bus 1060.

The memory 1030 included in the electronic device 1000 shown in FIG. 11 may include a memory device, according to various embodiments of the present disclosure. For example, the memory 1030 may operate in accordance with various embodiments described with reference to FIGS. 1 to 10.

Although the embodiments of the present disclosure have been described with reference to the accompanying drawings, it is to be apparent to those skilled in the art that the present disclosure may be manufactured in various forms without being limited to the above-described embodiments and may be embodied in other specific forms without departing from technical spirits and essential characteristics of the present disclosure. Thus, the above embodiments are to be considered in all respects as illustrative and not restrictive.

What is claimed is:

1. A memory device, comprising:
a memory cell array comprising a plurality of memory transistors and a memory capacitor; and
a peripheral circuit region at least partially overlapping the memory cell array in a first direction,
wherein the peripheral circuit region comprises:
a bias voltage generating circuit configured to generate a bias voltage and to provide the bias voltage to an individual circuit of the peripheral circuit region; and
a leakage current control circuit configured to generate a bias voltage control signal and to control, using the bias voltage control signal, a magnitude of a leakage current generated in the peripheral circuit region by the bias voltage,
wherein the leakage current control circuit comprises:
a test circuit configured to generate a test voltage based on the bias voltage;
a reference circuit configured to generate a reference voltage based on a power voltage; and
a differential amplifier configured to generate the bias voltage control signal by comparing the test voltage with the reference voltage,
wherein the test circuit comprises a first transistor having a first threshold voltage and a second transistor having a second threshold voltage different from the first threshold voltage, and
wherein the reference circuit comprises a third transistor having the first threshold voltage and a fourth transistor having the second threshold voltage.

2. The memory device of claim 1, wherein the peripheral circuit region further comprises a fifth transistor having the first threshold voltage and a sixth transistor having the second threshold voltage.

3. The memory device of claim 2, wherein a third ratio of a magnitude of the fifth transistor to a magnitude of the sixth transistor is equal to a first ratio of a magnitude of the first transistor to a magnitude of the second transistor, and
wherein the third ratio is equal to a second ratio of a magnitude of the third transistor to a magnitude of the fourth transistor.

4. The memory device of claim 2, wherein the bias voltage generating circuit is further configured to apply a first bias voltage is applied to a first body of the first transistor and a second body of the second transistor,
wherein the reference circuit is further configured to apply the power voltage to a third body of the third transistor and to a fourth body of the fourth transistor,
wherein the test circuit is further configured to generate the test voltage based on a first resistor and a test leakage current generated in the first transistor and the second transistor, and
wherein the reference circuit is further configured to generate the reference voltage based on a second resistor and a reference leakage current generated in the third transistor and the fourth transistor.

5. The memory device of claim 4, wherein the bias voltage generating circuit is further configured to:
generate a second bias voltage based on the bias voltage control signal; and
apply the second bias voltage to the first body of the first transistor and the second body of the second transistor.

6. The memory device of claim 5, wherein the bias voltage generating circuit is further configured to:
apply the second bias voltage to a fifth body of the fifth transistor and to a sixth body of the sixth transistor.

7. The memory device of claim 5, wherein, based on the second bias voltage being applied to the first body of the first transistor and the second body of the second transistor:
the test circuit is configured to generate a second test voltage based on the first resistor and a corrected test leakage current generated in the first transistor and the second transistor by the second bias voltage;
the reference circuit is configured to generate the reference voltage based on the second resistor and the reference leakage current generated in the third transistor and the fourth transistor; and
a magnitude of the second test voltage is equal to a magnitude of the reference voltage.

8. The memory device of claim 4, wherein the test circuit further comprises a test current mirror,
wherein the test current mirror comprises a seventh transistor and an eighth transistor,
wherein an end of the first transistor, an end of the second transistor, a drain electrode of the seventh transistor, a gate electrode of the seventh transistor, and a gate electrode of the eighth transistor are coupled with a first node,
wherein an end of the eighth transistor is coupled with a second node,
wherein the first resistor is between the second node and the power voltage, and comprises a first sub-resistor and a second sub-resistor,
wherein the reference circuit further comprises a reference current mirror,
wherein the reference current mirror comprises a ninth transistor and a tenth transistor,
wherein an end of the third transistor, an end of the fourth transistor, a drain electrode of the ninth transistor, a gate electrode of the ninth transistor, and a gate electrode of the tenth transistor are coupled with a third node,
wherein an end of the tenth transistor is coupled with a fourth node,
wherein the second resistor is between the fourth node and the power voltage, and
wherein a magnitude of the first sub-resistor is equal to a magnitude of the second resistor.

9. The memory device of claim 8, wherein the peripheral circuit region further comprises a mode selecting circuit configured to generate a resistance selection signal and to control, using the resistance selection signal, the magnitude of the second sub-resistor,
wherein the second sub-resistor has a first magnitude based on the mode selecting circuit generating a first resistance selection signal, and
wherein the second sub-resistor has a second magnitude different from the first magnitude based on the mode selecting circuit generating a second resistance selection signal different from the first resistance selection signal.

10. The memory device of claim 8, wherein the test voltage is measured at the second node, and
wherein the reference voltage is measured at the fourth node.

11. The memory device of claim 4, wherein the test circuit further comprises a test current mirror,
wherein the test current mirror comprises a seventh transistor and an eighth transistor,
wherein an end of the first transistor, an end of the second transistor, a drain electrode of the seventh transistor, a gate electrode of the seventh transistor, and a gate electrode of the eighth transistor are coupled with a first node,
wherein an end of the eighth transistor is coupled with a second node,
wherein the first resistor comprises a first sub-resistor and a second sub-resistor,
wherein the first sub-resistor is between the first node and the power voltage,
wherein the second sub-resistor is between the second node and the power voltage,
wherein the reference circuit further comprises a reference current mirror,
wherein the reference current mirror comprises a ninth transistor and a tenth transistor,
wherein an end of the third transistor, an end of the fourth transistor, a drain electrode of the ninth transistor, a gate electrode of the ninth transistor, and a gate electrode of the tenth transistor are coupled with a third node,
wherein an end of the tenth transistor is coupled with a fourth node,
wherein the second resistor is between the fourth node and the power voltage, and
wherein a magnitude of the second sub-resistor is equal to a magnitude of the second resistor.

12. The memory device of claim 11, wherein the test circuit further comprises a third resistor between the first node and the power voltage,
wherein the reference circuit further comprises a fourth resistor between the third node and the power voltage, and
wherein a magnitude of the third resistor is equal to a magnitude of the fourth resistor.

13. The memory device of claim 1, wherein the bias voltage generating circuit comprises at least one of a charge pump or a regulator, and
wherein the bias voltage generating circuit is configured to generate the bias voltage based on the bias voltage control signal.

14. A memory device, comprising:
a memory cell array comprising a plurality of memory transistors and a memory capacitor; and
a peripheral circuit region at least partially overlapping the memory cell array in a first direction,
wherein the peripheral circuit region comprises:
a bias voltage generating circuit configured to generate a bias voltage and to provide the bias voltage to an individual circuit of the peripheral circuit region; and
a leakage current control circuit configured to generate a bias voltage control signal and to control, using the bias voltage control signal, a magnitude of a leakage current generated in the peripheral circuit region by the bias voltage,
wherein the leakage current control circuit comprises:
a test circuit configured to generate a test voltage based on the bias voltage; and
a reference circuit configured to generate a reference voltage based on a power voltage, and
wherein the leakage current control circuit is further configured to generate the bias voltage control signal that controls the bias voltage generating circuit to generate the bias voltage such that a magnitude of the test voltage is equal to a magnitude of the reference voltage.

15. The memory device of claim 14, wherein the test circuit comprises a test transistor and a test resistor,
wherein the test circuit is configured to:
generate a test leakage current in the test transistor by applying the bias voltage being to a test body of the test transistor; and
generate the test voltage based on the test leakage current and the test resistor,
wherein the reference circuit comprises a reference transistor and a reference resistor, and
wherein the reference circuit is configured to:
generate a reference leakage current in the reference transistor by applying the power voltage to a reference body of the reference transistor; and
generate the reference voltage based on the reference leakage current and the reference resistor.

16. The memory device of claim 15, wherein a magnitude of the test voltage is greater than a magnitude of the reference voltage.

17. The memory device of claim 16, wherein the bias voltage generating circuit is further configured to generate a second bias voltage having a magnitude greater than a magnitude of the bias voltage based on the bias voltage control signal,
wherein the test circuit is further configured to:
generate a corrected test leakage current in the test transistor by applying the second bias voltage being to the test body of the test transistor; and
generate a second test voltage based on the corrected test leakage current and the test resistor, and
wherein the magnitude of the second test voltage is equal to the magnitude of the reference voltage.

18. The memory device of claim 15, wherein a magnitude of the test voltage is less than a magnitude of the reference voltage.

19. The memory device of claim 18, wherein the bias voltage generating circuit is further configured to generate a second bias voltage having a magnitude less than a magnitude of the bias voltage based on the bias voltage control signal,
wherein the test circuit is further configured to:
generate a corrected test leakage current in the test transistor by applying the second bias voltage to the test body of the test transistor; and
generate a second test voltage based on the corrected test leakage current and the test resistor, and
wherein a magnitude of the second test voltage is equal to the magnitude of the reference voltage.

20. A memory device, comprising:
a memory cell array comprising a plurality of memory transistors and a memory capacitor; and
a peripheral circuit region at least partially overlapping the memory cell array in a first direction,
wherein the peripheral circuit region comprises:
a bias voltage generating circuit configured to generate a bias voltage and to provide the bias voltage to an individual circuit of the peripheral circuit region, and
a leakage current control circuit configured to generate a bias voltage control signal and to control, using the bias voltage control signal, a magnitude of a leakage current generated in the peripheral circuit region by the bias voltage,
wherein the leakage current control circuit comprises:
a test circuit configured to generate a test voltage based on the bias voltage;
a reference circuit configured to generate a reference voltage based on a power voltage; and
a differential amplifier configured to generate the bias voltage control signal based on the test voltage and the reference voltage,
wherein the test circuit comprises a first transistor having a first threshold voltage and a second transistor having a second threshold voltage,
wherein the reference circuit comprises a third transistor having the first threshold voltage and a fourth transistor having the second threshold voltage,
wherein the test circuit is further configured to generate the test voltage based on a first resistor and a test leakage current generated in the first transistor and the second transistor based on a first bias voltage being applied to a first body of the first transistor and a second body of the second transistor,
wherein the reference circuit is further configured to generate the reference voltage based on a second resistor and a reference leakage current generated in the third transistor and the fourth transistor based on the power voltage being applied to a third body of the third transistor and a fourth body of the fourth transistor,
wherein the differential amplifier is further configured to generate the bias voltage control signal based on the test voltage being different to the reference voltage,
wherein the bias voltage generating circuit is further configured to generate a second bias voltage based on the bias voltage control signal,
wherein the test circuit is further configured to generate a second test voltage based on the first resistor and a corrected test leakage current generated in the first transistor and the second transistor based on the second bias voltage being applied to the first body of the first transistor and the second body of the second transistor, and
wherein a magnitude of the second test voltage is equal to a magnitude of the reference voltage.
